(19) United States
(12) Patent Application Publication
(10) Pub. No.: US 2025/0151248 A1
(43) Pub. Date: May 8, 2025

(54) EMC SCATTERING SHIELD APPARATUS

(71) Applicant: International Business Machines Corporation, Armonk, NY (US)

(72) Inventors: Samuel R. Connor, Apex, NC (US); Arthur J. Higby, Cottekill, NY (US); John S. Werner, Fishkill, NY (US)

(21) Appl. No.: 18/503,408

(22) Filed: Nov. 7, 2023

(51) Int. Cl. H05K 9/00

(52) U.S. Cl. CPC H05K 9/002

(57) ABSTRACT

An EMC scattering shield apparatus and method of use is provided. The EMC scattering shield apparatus includes a mounting feature that permits the EMC scattering shield apparatus to attach to an external component. The EMC scattering shield apparatus includes an EMC scattering shield to scatter energy that may be emitted from the product and to provide immunity by scattering energy within the environment. The EMC scattering shield apparatus an extension arm configured to position the EMC scattering shield at a desired distance away from the external component. The EMC scattering shield apparatus can include a rotation hinge that permits the EMC scattering shield to rotate away from the external component

### BACKGROUND

The present disclosure relates to electromagnetic compatibility (EMC), and more specifically, to providing EMC compliance in a product without having to redesign the end product.

Electromagnetic Compatibility or EMC refers to the ability of electronic devices, equipment, and systems to operate properly in the presence of electromagnetic interference (EMI) and without causing interference to other nearby devices. Electromagnetic interference occurs when electromagnetic energy emitted by one device disrupts the operation of another device. This interference can lead to malfunctions, data corruption, communication errors, or even complete system failures. It can be caused by various sources such as power lines, radio waves, wireless devices, motors, etc.

EMC is crucial for computer equipment because computers and related devices generate and are susceptible to electromagnetic emissions. Computers contain numerous electronic components and interconnected circuits that can emit electromagnetic radiation or be affected by it. Without proper EMC design and testing, computer equipment can experience various problems.

For example, electromagnetic interference can disrupt the normal operation of computer equipment, leading to crashes, errors, and data loss. Ensuring EMC helps maintain the reliable functioning of the equipment.

In another instance, such as in a data center, there are many computer systems and devices that operate in close proximity to each other. In the absence of EMC, one device may interfere with the operation of another, causing compatibility issues and disruptions.

Furthermore, most countries have regulations and standards related to EMC to ensure that electronic devices don't cause harmful interference to other equipment or public services. Compliance with these regulations is mandatory for manufacturers to legally sell their products.

EMC is also important for the safety of computer equipment and the users. Malfunctions or interference caused by electromagnetic emissions could potentially pose risks of electric shock, fire, or other hazardous situations.

To achieve EMC, manufacturers employ various design techniques, shielding, grounding, filtering, and testing procedures. These measures help minimize the generation and susceptibility of electromagnetic emissions, ensuring that computer equipment can operate reliably and without causing interference to other devices.

### SUMMARY

In some aspects, the techniques described herein relate to an EMC scattering shield apparatus including: a mounting feature configured to attach the EMC scattering shield apparatus to an external component; an EMC scattering shield to scatter energy that may be emitted from the product and to provide immunity by scattering energy within the environment; and an extension arm configured to position the EMC scattering shield at a desired distance away from the external component.

In some aspects, the techniques described herein relate to a method of controlling an EMC scattering shield apparatus during a service action, the method including: placing an external component into a service mode; opening the EMC scattering shield apparatus, EMC scattering shield apparatus including; a mounting feature configured to attach the EMC scattering shield apparatus to an external component; an EMC scattering shield to scatter energy that may be emitted from the product and to provide immunity by scattering energy within the environment; an extension arm configured to position the EMC scattering shield at a desired distance away from the external component; and a rotation hinge configured to permit the EMC scattering shield to rotate away from the external component; performing the service action on the external component; and closing the EMC scattering shield apparatus.

### BRIEF DESCRIPTION OF THE DRAWINGS

FIG. 1 is a perspective view of an EMC scattering shield apparatus installed on a drawer or server component according to embodiments of the present disclosure.

FIG. 2 is a rear view of the drawer or server component with the EMC scattering shield apparatus installed according to embodiments of the present disclosure.

FIG. 3 is a perspective view of an EMC scattering shield apparatus installed on a drawer or server component according to embodiments of the present disclosure.

FIG. 4 is a is a rear view of the drawer or server component with the EMC scattering shield apparatus installed according to embodiments of the present disclosure.

FIG. 5A is a perspective view of the EMC scattering shield apparatus having angled slots according to embodiments of the present disclosure.

FIG. 5B is a is a perspective view of the EMC scattering shield having angled slots according to embodiments of the present disclosure.

FIG. 5C is a cutaway view of the EMC scattering shield having angled slots according to embodiments of the present disclosure.

FIG. 6 is a flow diagram illustrating a process for servicing a drawer or server subcomponent according to embodiments of the present disclosure.

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to electromagnetic compatibility (EMC), more particular aspects relate to providing EMC compliance in a product without having to redesign the end product. While the present disclosure is not necessarily limited to such applications, various aspects of the disclosure may be appreciated through a discussion of various examples using this context.

Servers and server subcomponents are required to meet a set of international and country specific electromagnetic compatibility (EMC) standards before they can be offered to customers. These standards include, for example, CISPR 22 and CISPR 32 from the International Special Committee on Radio Interference, EN 55024, EN 55032, EN 61000-3-11, and EN 61000-3-12 of the European Union, FCC 47 CFR Part 15-Subpart B of the United States, etc. These standards ensure that electrical equipment and systems function acceptably within their electromagnetic environment. Specifically, by limiting the unintentional generation, propagation, and reception of electromagnetic energy. This electromagnetic energy when unlimited can cause unwanted effects such as electromagnetic interference (EMI) or physical damage to the equipment.

EMC can be classified into three main classes, emissions, susceptibility, and immunity. Emissions is the generation of electromagnetic energy, whether deliberate or accidental, by some source and its release into the environment Susceptibility is the tendency of electrical equipment to malfunction or break down in the presence of unwanted emissions. This is also known as radio frequency interference (RFI). Immunity is the ability of equipment to function correctly in the presence of RFI, with the discipline of “hardening” equipment being known equally as susceptibility or immunity.

For systems that come in a rack with metal doors, the doors often assist in reducing emissions and increasing immunity for the subcomponents by scattering the energy as it enters or exits the rack such that the emissions are not all focused in one direction. With the introduction of certain rack mount offerings where the server subcomponents (processor drawers, IO drawers, switches, etc.) are offered separately and installed in a customer rack, a problem has been identified due to the fact that many customers do not hang metal doors on their racks. As such the metal doors could no longer be relied upon for scattering the energy to meet EMC standards.

Previously, to address this problem, a statement has been added in the systems user's manual that requires customers to hang metal doors on their rack. However, this led to unhappy customers who did not want to hang doors on their racks for a number of reasons. This approach also requires customers to purchase rack doors if they wish to comply. This results in added costs for the procurement of the systems. Further, there are customers that may either never read the manual or ignore the requirement. This results in them operating systems that do not meet applicable requirements and may put them at risk of being fined or otherwise punished by relevant authorities.

To address this issue an EMC shield apparatus was developed for drawer level EMC scattering. The shield apparatus will help ensure that the required compliance standards for EMC is met. The shield apparatus is designed to scatter the energy due to radiated emissions and/or to provide immunity to a desired area. The EMC shield apparatus can be connected to standard electronic industry alliance (EIA) rails or to the server subcomponent itself. The EMC shield apparatus allows for the egress of cables as well as to permit service actions to be performed on the component while providing the required EMC. Through the design of the EMC shield apparatus, manufacturers of these types of systems are provided with a relatively inexpensive solution that can be implemented to meet various compliance standards. The EMC shield apparatus also provides manufacturers a solution that can be implemented in the event that the particular system encounters an EMC failure late in the program's development. This allows for the maintaining of already existing release and shipping schedules. The shield also benefits customers as they do not need to install the rack doors or have to look to the manual to understand the EMC risks.

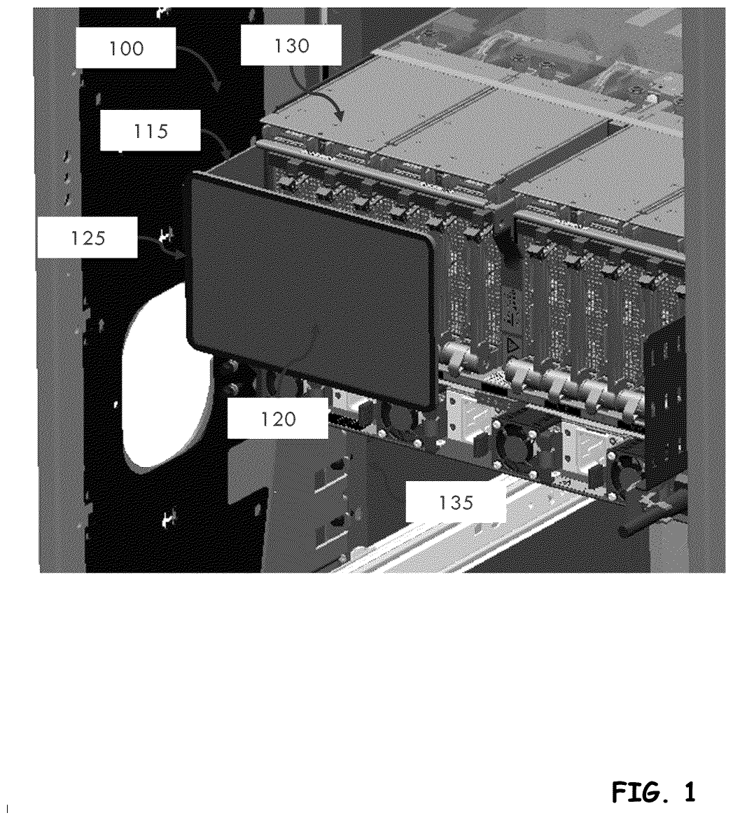

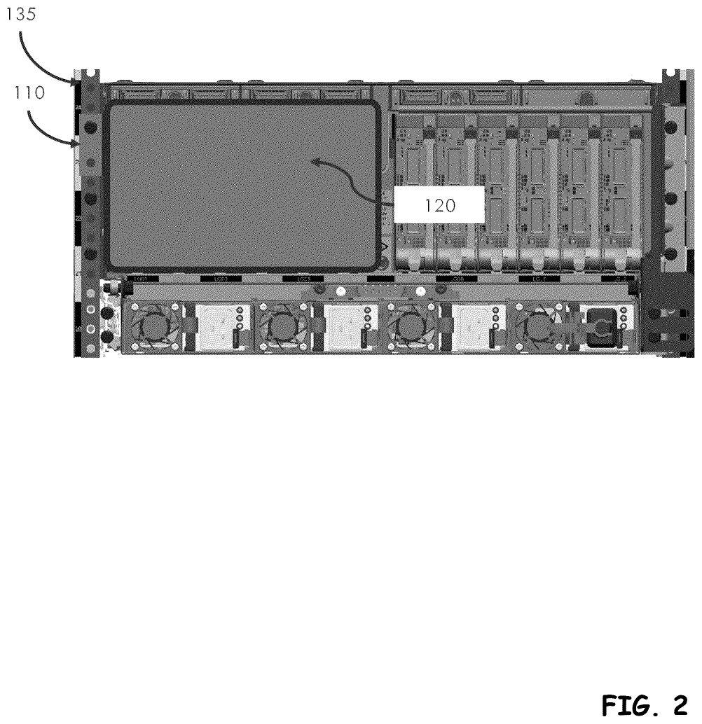

FIG. 1 is a perspective view of an EMC scattering shield apparatus 100 installed on a drawer or server component. FIG. 2 is a rear view of the drawer or server component with the EMC scattering shield apparatus installed. While the EMC scattering shield apparatus 100 is illustrated in the figures installed of the rear, it should be noted that it can be implemented on the front, sides, top, or bottom of drawer or server subcomponent.

The EMC scattering shield apparatus 100 includes a mounting feature 110, an extension arm 115, an EMC scattering shield 120, and an optional rotation hinge 125. The components of the EMC scattering shield apparatus 100 are made from conductive materials such as metal and connected to the same ground potential as drawer or server subcomponent 130. However other conductive materials can be used such as graphite or graphene. In some embodiments only the EMC scattering shield 120 is connected to the same ground potential as drawer or server subcomponent 130 using a ground strap or other connecting means.

The mounting feature is a component of the EMC scattering shield apparatus that allows for the attachment of the apparatus to the corresponding equipment. The mounting features 110 allows the EMC scattering shield apparatus 100 to be attached to standard EIA rails 135 on either side of an equipment rack. In some embodiments, the position of mounting feature 110 is fixed and designed around unused EIA holes for specific servers and/or subcomponents. However, in other embodiments the mounting feature 110 is configured to attach to different components. For example, in some embodiments, the mounting feature 110 is designed to attach directly to a drawer or server subcomponent 130. In some embodiments, the mounting feature 110 is designed to attach to a cable spine that runs down the center of an equipment rack

The extension arm is a component of the EMC scattering shield apparatus 100 that is configured to position the EMC scattering shield away from the corresponding equipment. The extension arm 115 extends outward from EIA rails 135 and runs alongside the drawer or server subcomponent 130. This allows for the EMC scattering shield 120 to be positioned at a desired distance away from drawer or server subcomponent 130. The length of extension arm 115 is enough to allow for cable egress. The closer to the drawer or subcomponent 130 the shield 120 is the less the chance that emissions potentially can escape from the enclosure at an angle that does not get blocked by shield 120 itself. However, depending on the desired protection levels, different distances can be used for the shield 120. Further, the extension arm 115 should be positioned far enough away from the subcomponent 130 so as not cause thermal issues by trapping heat near the drawer or server subcomponent 130 while still permitting the EMC scattering shield 120 to perform as needed. In some embodiments, the extension arm 115 is adjustable. For example, the extension arm 115 can include features that permit it to telescope in and out to permit access to the cables or otherwise control the shielding. In another example, the extension arm 115 can contain multiple predetermined positions where the arm can be extended and fixed into position with a screw, notch or other locking mechanism.

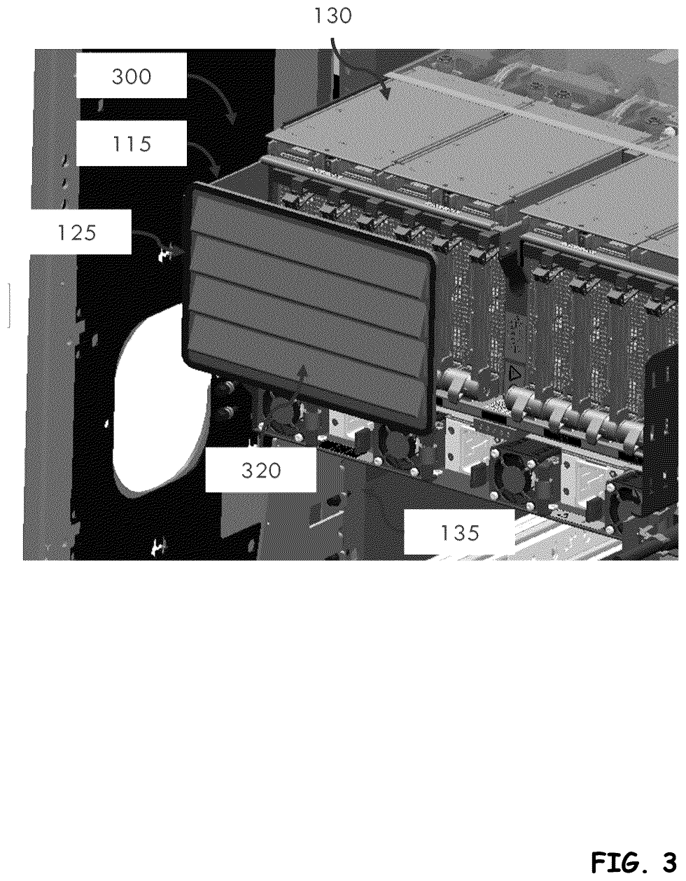

The EMC scattering shield 120 is a component of the apparatus 100 that is configured to obstruct and scatter energy due to radiated emissions from the product and to provide immunity from EMC by scattering energy within the environment that could impact the operation of drawer or server subcomponent 130. In the embodiments illustrated in FIGS. 1 and 2, the EMC scattering shield 120 is formed of a solid piece of conductive material. However, in other embodiments, perforations are added to the EMC scattering shield 120 to help improve thermal performance. When perforations are present, if there is sufficient depth available the perforations can be angled so as to direct radiated emission scattering in a particular direction, away from receiving antennas used during EMC compliance testing. This can also assist with immunity when transmit antennas are used during EMC compliance testing. In some embodiments this direction of the perforations is downwards. The size of the perforation openings can be adjusted based on the highest frequency of concern. When sizing the perforations for a frequency of concern, the perforation openings should be smaller than a quarter wavelength of the highest frequency of concern. A more detailed description of the shield with perforations is discussed with respect to FIGS. 3-5 below.

In some embodiments, the length, width, and height of the EMC scattering shield 120 can be adjusted for targeted scattering and minimized impact to thermal performance and when performing service actions. The EMC scattering shield 120 can be sized such that it only screens a couple PCIe slots (e.g., slots that are dedicated to higher power or higher emission cards) or can be sized such that it covers half or the full width of the drawer or server subcomponent 130 In some embodiments, EMC scattering shield 120 contains an EMC absorbing material such as Laird Eccosorb® of Laird Technologies Inc of Chesterfield MO or Schlegel BandSorb® of Schlegel Electronic Materials Asia LTD of Hong Kong SAR China.

The rotation hinge 125 is a component of the EMC scattering shield apparatus that permits the EMC scattering shield 125 to rotate. The EMC scattering shield 120 can be rotated away from drawer or server subcomponent 130 for service or other reasons. In some embodiments, the rotation hinge 125 can allow the EMC scattering shield 120 to be folded out away from drawer or server subcomponent 130 (in line with extension arm 115), rotated upward 90 degrees about the top corner near extension arm 115, or rotated downward 90 degrees about the bottom left corner near extension arm 115. In some embodiments the rotation hinge 125 allows EMC scattering shield 120 to be slid up or down. This helps with allowing the mounting means 110 to be attached in a location on the EIA rails that is open.

It should be noted that the rotational hinge 125 need not be present. In those instances, the EMC scattering shield 120 is attached or removed when desired. For example, the EMC scattering shield 120 can be snaped or screwed to extension arm 115.

In some embodiments the rotation hinge 125 is rotated manually by a user performing installation or service. However, in some embodiments a motor (not illustrated) is present which allows the rotation hinge 125 to be rotated electronically when service is required. The rotational hinge 125 can include a locking mechanism to keep it in place when the apparatus 100 is in a deployed position.

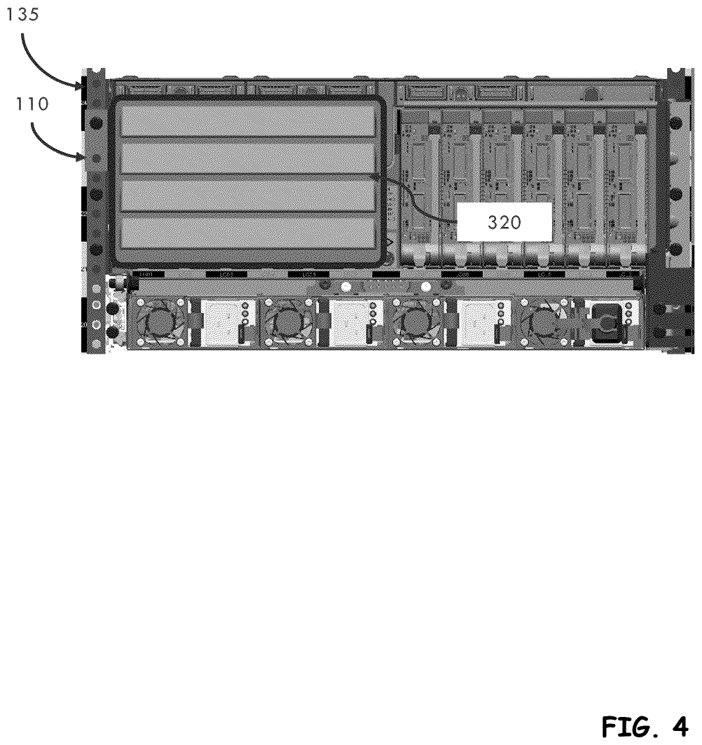

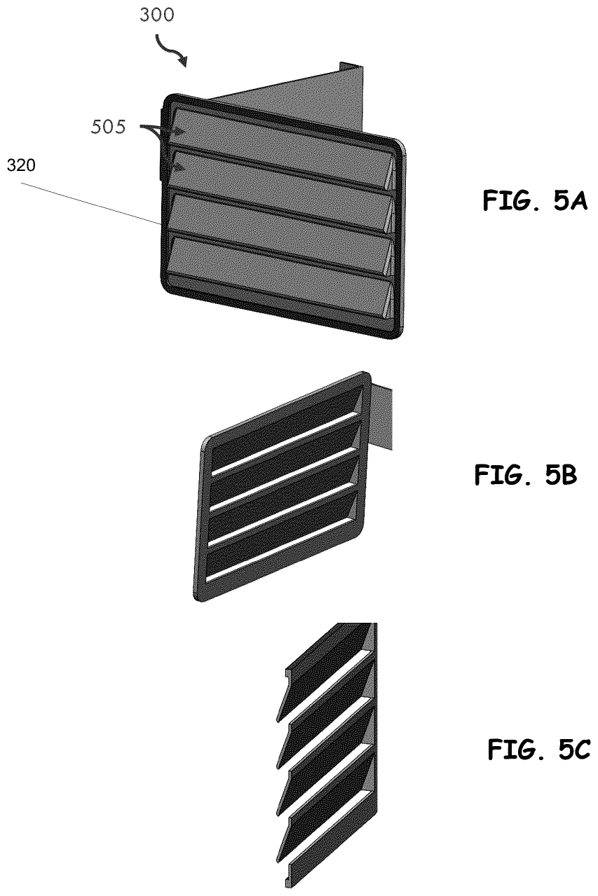

FIG. 3 is a perspective view of an EMC scattering shield apparatus 300 installed on a drawer or server component. FIG. 4 is a is a rear view of the drawer or server component with the EMC scattering shield apparatus installed. FIG. 5A is a perspective view of the EMC scattering shield apparatus 300 having angled slots 505. FIG. 5B is a is a perspective view of the EMC scattering shield 320 having angled slots 505. FIG. 5C is a cutaway view of the EMC scattering shield 320 having angled slots 505. For purposes of this discussion FIGS. 3-5 will be discussed together.

The EMC scattering shield apparatus 300 like EMC scattering shield apparatus 100 include mounting means 110, extension arm 115, an EMC scattering shield 320, and rotation hinge 125. Similarly, the components of EMC scattering shield apparatus 300 are conductive (e.g., metal) and connected to the same ground potential as drawer or server subcomponent 130. In some embodiments only the EMC scattering shield 120 is connected to the same ground potential as drawer or server subcomponent 130 using a ground strap or other connecting means.

As mentioned above, the mounting means 110, extension arm 115, and rotation hinge 125 are all similar to those discussed above with respect to FIGS. 1 and 2.

The EMC scattering shield 320 likewise is configured to obstruct and scatter energy that may be emitted from the product and to provide immunity by scattering energy within the environment that could impact the operation of drawer or server subcomponent 130. Unlike EMC scattering shield 120, the EMC scattering shield 320 contains solid angled slats 505. The angled slats 505 direct radiated emission scattering downward, away from the receiving antennas used during EMC compliance testing. They also assist with immunity when transmit antennas are used during EMC compliance testing. The number of angled slats 505 can be adjusted based upon the needs of the system. In some embodiments, perforations may be added to angled slats 505 to improve thermal performance of the apparatus 300. Further, the size of the perforation openings can be adjusted based on the highest frequency of concern. The higher the frequency the smaller the openings need to be. In some embodiments, the perforation openings are smaller than a quarter wavelength of the highest frequency of concern. Further, in some embodiments, the length, width, and height of EMC scattering shield 320 can be adjusted for targeted scattering and minimized impact to thermal performance and when performing service actions. Like scattering shield 120, in some embodiments, the EMC scattering shield 320 contains an EMC absorbing material such as Laird Eccosorb® of Laird Technologies Inc of Chesterfield MO or Schlegel BandSorb® of Schlegel Electronic Materials Asia LTD of Hong Kong SAR China.

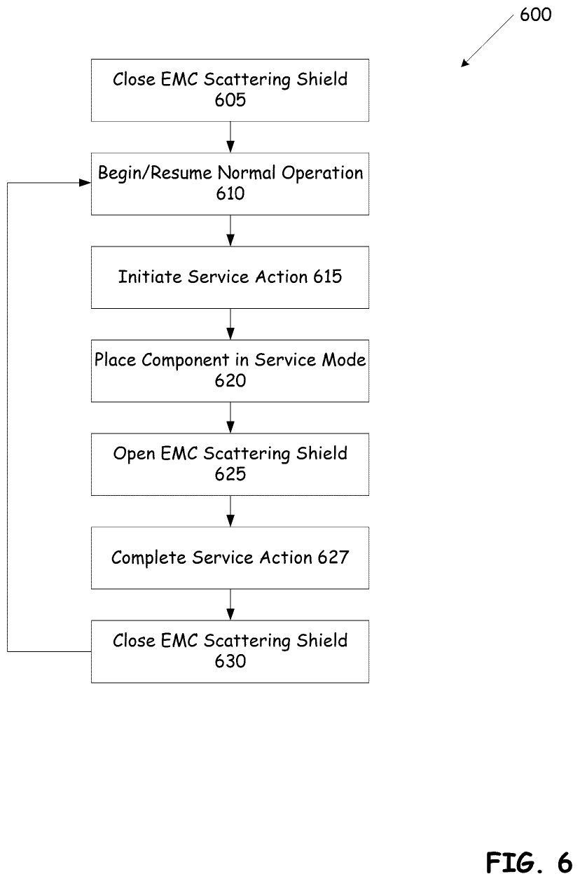

FIG. 6 is a flow diagram illustrating a process 600 for servicing a drawer or server subcomponent 130. This process ensures that the EMC scattering shield apparatus 100 or 300 is moved out of the way during the servicing and put back in place after servicing has been completed. The logic needed to implement process 600 can be contained in memory/storage of a system service element (SE) or baseboard management controller (BMC) of the EMC scattering shield apparatus 100, 300. In order to implement process 600 communication is required between the system SE or BMC and the EMC scattering shield apparatus 100, 300. The components required to provide this communication and logic are not illustrated in the figures. As discussed above, the rotation hinge 125 can contain a motor such that EMC scattering shield apparatus 100, 300 can be opened and closed via an electric motor. In some embodiments the motor can be controlled with commands to only open or close during service.

The process 600 begins by placing the EMC scattering shield apparatus 100, 300 in the closed position. This is illustrated at step 605. The closed position is illustrated by the apparatuses as shown in FIGS. 1-4. At this point in some embodiments, the EMC scattering shield apparatus 100, 300 can send a signal to the SE or BMC that the rotational hinge 125 is present or in the closed position.

The process continues by either beginning or continuing the operation of drawer or server subcomponent 130. This is illustrated at step 610. If some or all operation was previously while drawer or server subcomponent 130 was in service mode, that limitation is removed and drawer or server subcomponent 130 can be made fully operational.

The drawer or sever subcomponent 130 proceeds to operate until such time as a service action is initiated. The initiation of the service action is illustrated at step 615. In some embodiments, a service action may be initiated though the SE or BMC. In some embodiments the action can be implemented using an interrupt. In some embodiments, the specific part that is to be serviced is indicated in this service action.

In response to a service action being commanded, the subcomponent 130 is placed in a service mode. This is illustrated at step 620. When in the service mode, some or all of the operation of the subcomponent 130 can be limited. However, in some embodiments the subcomponent 130 can remain fully operational with the exception of the part/component being serviced. In some embodiments, putting the drawer or server subcomponent 130 in service mode unlocks EMC scattering shield apparatus 100, 300 thus, allowing it to be rotated or removed. However, in some embodiments, the rotation or movement of the EMC scattering shield 120, 320 initiates the service mode.

Once unlocked the EMC scattering shield apparatus 100, 300 is opened. This is illustrated at step 625. In some embodiments the opening can be executed manually by a service person. Alternatively, if a motor is present the motor can rotate the apparatus 100, 300 to the open position. An indication of this opening can be sent to the SE or BMC that rotational hinge 125 is in an open position via a signal. Alternatively, this indication can be based on the signal to EMC scattering shield apparatus 100, 300 being lost. For example, the service person may be required to unplug EMC scattering shield apparatus 100, 300 when removing it before they can perform the service. In some embodiments, the SE or BMC may provide instructions to the service person at this point for performing whatever service is required.

Once the service has been completed the process waits for the service person to close the apparatus 100, 300. This is illustrated at step 630. Again the closing process can be done manually by the person or if present by having the motor rotate the apparatus 100, 300 into the closed position. At this point the process returns to step 610 and continues.

The present disclosure can be considered as well in view of the following examples.

Example 1. An EMC scattering shield apparatus comprising: a mounting feature configured to attach the EMC scattering shield apparatus to an external component; an EMC scattering shield to scatter energy that may be emitted from the product and to provide immunity by scattering energy within the environment; and an extension arm configured to position the EMC scattering shield at a desired distance away from the external component.

Example 2. The EMC scattering shield apparatus of example 1, wherein the external component is selected from the group of a drawer, a server subcomponent, a cable management spine, server rack, and EIA rails.

Example 3. The EMC scattering shield apparatus of examples 1-2, wherein the extension arm is configured to move closer to or further from a drawer or subcomponent in response to an action from a user.

Example 4. The EMC scattering shield apparatus of example 3 wherein the movement of the EMC scattering shield permits cable egress to the external component.

Example 5. The EMC scattering shield apparatus of any of the preceding examples, further comprising: a rotation hinge configured to permit the EMC scattering shield to rotate away from the external component.

Example 6. The EMC scattering shield apparatus of example 5 wherein the rotational hinge is motorized.

Example 7. The EMC scattering shield apparatus of examples 5 and 6 further comprising: logic configured to respond to the rotation of the EMC scattering shield from a closed position and an open position, the logic causing the external component to enter a service mode in response to rotation into the open position.

Example 8. The EMC scattering shield apparatus of example 7, wherein the logic is configured to remove the service mode condition in response to the EMC scattering shield returning to the closed position.

Example 9. The EMC scattering shield apparatus of examples 5-8, wherein the rotational hinge rotates the EMC scattering shield away from the external component in line with the extension arm.

Example 10. The EMC scattering shield apparatus of any of the preceding examples, wherein the EMC scattering shield is solid.

Example 11. The EMC scattering shield apparatus of any of the preceding examples, wherein the EMC scattering shield is perforated.

Example 12. The EMC scattering shield apparatus of any of the preceding examples, wherein the perforations are angled downward relative to the external component.

Example 13. The EMC scattering shield apparatus of any of the preceding examples, wherein the perforations are smaller than a quarter wavelength of a highest frequency of concern for EMC protection.

Example 14. The EMC scattering shield apparatus any of the preceding examples, wherein the EMC scattering shield includes a plurality of slats.

Example 15. The EMC scattering shield apparatus of any of the preceding examples, wherein the slats are angled downward relative to the external component.

Example 16. A method of controlling an EMC scattering shield apparatus during a service action, the method comprising: placing an external component into a service mode; opening the EMC scattering shield apparatus, EMC scattering shield apparatus comprising; a mounting feature configured to attach the EMC scattering shield apparatus to an external component; an EMC scattering shield to scatter energy that may be emitted from the product and to provide immunity by scattering energy within the environment; an extension arm configured to position the EMC scattering shield at a desired distance away from the external component; and a rotation hinge configured to permit the EMC scattering shield to rotate away from the external component; performing the service action on the external component; and closing the EMC scattering shield apparatus.

Example 17. The method of example 16, wherein putting the external component in service mode unlocks the EMC scattering shield apparatus.

Example 18. The method of examples 16 and 17, wherein putting the component in service mode limits at least a portion of the functionality of the external component

Example 19. The method of examples 16-18, wherein opening of an EMC scattering shield of the EMC scattering shield apparatus is controlled by a motor that rotates the rotational hinge.

Example 20. The method of examples 16-19 wherein in response to closing the EMC scattering shield apparatus the method further comprising: returning the external component to a normal operational mode.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An EMC scattering shield apparatus comprising:
a mounting feature configured to attach the EMC scattering shield apparatus to an external component;
an EMC scattering shield to scatter energy that may be emitted from the product and to provide immunity by scattering energy within the environment; and
an extension arm configured to position the EMC scattering shield at a desired distance away from the external component.

2. The EMC scattering shield apparatus of claim 1, wherein the external component is selected from the group of a drawer, a server subcomponent, a cable management spine, server rack, and EIA rails.

3. The EMC scattering shield apparatus of claim 1, wherein the extension arm is configured to move closer to or further from a drawer or subcomponent in response to an action from a user.

4. The EMC scattering shield apparatus of claim 3 wherein the movement of the EMC scattering shield permits cable egress to the external component.

5. The EMC scattering shield apparatus of claim 1, further comprising:
a rotation hinge configured to permit the EMC scattering shield to rotate away from the external component.

6. The EMC scattering shield apparatus of claim 5 wherein the rotational hinge is motorized.

7. The EMC scattering shield apparatus of claim 5 further comprising:
logic configured to respond to the rotation of the EMC scattering shield from a closed position to an open position, the logic causing the external component to enter a service mode in response to rotation into the open position.

8. The EMC scattering shield apparatus of claim 7, wherein the logic is configured to remove the service mode condition in response to the EMC scattering shield returning to the closed position.

9. The EMC scattering shield apparatus of claim 5, wherein the rotational hinge rotates the EMC scattering shield away from the external component in line with the extension arm.

10. The EMC scattering shield apparatus of claim 1, wherein the EMC scattering shield is solid.

11. The EMC scattering shield apparatus of claim 1, wherein the EMC scattering shield is perforated.

12. The EMC scattering shield apparatus of claim 11, wherein the perforations are angled downward relative to the external component.

13. The EMC scattering shield apparatus of claim 11, wherein the perforations are smaller than a quarter wavelength of a highest frequency of concern for EMC protection.

14. The EMC scattering shield apparatus of claim 1, wherein the EMC scattering shield includes a plurality of slats.

15. The EMC scattering shield apparatus of claim 14, wherein the slats are angled downward relative to the external component.

16. A method of controlling an EMC scattering shield apparatus during a service action, the method comprising:
placing an external component into a service mode;
opening the EMC scattering shield apparatus, EMC scattering shield apparatus comprising;
a mounting feature configured to attach the EMC scattering shield apparatus to an external component;
an EMC scattering shield to scatter energy that may be emitted from the product and to provide immunity by scattering energy within the environment;
an extension arm configured to position the EMC scattering shield at a desired distance away from the external component; and
a rotation hinge configured to permit the EMC scattering shield to rotate away from the external component;
performing the service action on the external component; and
closing the EMC scattering shield apparatus.

17. The method of claim 16, wherein putting the external component in service mode unlocks the EMC scattering shield apparatus.

18. The method of claim 16, wherein putting the component in service mode limits at least a portion of the functionality of the external component.

19. The method of claim 16, wherein opening of an EMC scattering shield of the EMC scattering shield apparatus is controlled by a motor that rotates the rotational hinge.

20. The method of claim 16 wherein in response to closing the EMC scattering shield apparatus the method further comprising:
returning the external component to a normal operational mode.
